(19) United States
(12) Patent Application Publication
(10) Pub. No.: US 2025/0311443 A1
(43) Pub. Date: Oct. 2, 2025

(54) BACKEND COMPATIBLE DIODES FOR INTEGRATED CIRCUIT DEVICES

(71) Applicant: Intel Corporation, Santa Clara, CA (US)

(72) Inventors: Abhishek A. Sharma, Portland, OR (US); Sagar Suthram, Portland, OR (US); Tahir Ghani, Portland, OR (US); Wilfred Gomes, Portland, OR (US); Anand S. Murthy, Portland, OR (US)

(21) Appl. No.: 18/619,727

(22) Filed: Mar. 28, 2024

(51) Int. Cl. H01L 27/02; H01L 23/522; H01L 29/872

(52) U.S. Cl. CPC H10D 89/611; H01L 23/5226; H10D 8/60

(57) ABSTRACT

A diode is included within a metallization stack of an integrated circuit device. The diode may be a thin film diode with two metal plates and a material between the metal plates. The material may be a semiconductor, forming a Schottky diode, or an insulator, forming a metal-insulator-metal diode. The diode may be electrically coupled to a transistor layer to provide electrostatic discharge protection.

### BACKGROUND

Electrostatic discharge (ESD) events can be damaging for electronic devices. Transistors and other semiconductor-based devices typically have a voltage tolerance; if the voltage tolerance for a particular device is exceeded, the device may be damaged or degraded. ESD events can create voltage spikes or excess charges that can damage these electronic devices. Thus, when designing IC devices or packages, it is useful to have a way to protect against ESD events.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIGS. 1A and 1B illustrate two example cross-sections of a diode that may be used for mitigating ESD events, according to some embodiments of the present disclosure.

FIGS. 2A-2C illustrate different cross sections of an IC device having a diode within a metal layers, according to some embodiments of the present disclosure.

FIG. 3 is a cross-section of another embodiment of a diode that may be included in a metal layer, according to some embodiments of the present disclosure.

FIG. 4 is a cross-section of a set of diodes that may be included in a metal layer, according to some embodiments of the present disclosure.

FIGS. 5A-5C illustrate two cross-sections of a set of diodes in a metal layer and a top-down illustration of the diodes, according to some embodiments of the present disclosure.

FIGS. 6A and 6B are top views of a wafer and dies that include one or more metal layers with at least one ESD diode in accordance with any of the embodiments disclosed herein.

FIG. 7 is a cross-sectional side view of an IC device that may include one or more metal layers with at least one ESD diode in accordance with any of the embodiments disclosed herein.

FIG. 8 is a cross-sectional side view of an IC device assembly that may include metal layers with at least one ESD diode in accordance with any of the embodiments disclosed herein.

FIG. 9 is a block diagram of an example computing device that may include one or more metal layers with at least one ESD diode in accordance with any of the embodiments disclosed herein.

FIG. 10 is a block diagram of an example processing device that may include one or more IC devices with one or more metal layers with at least one diode in accordance with any of the embodiments disclosed herein.

### DETAILED DESCRIPTION

### Overview

The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

ESD diodes can be used to manage ESD events in an integrated circuit (IC) device. ESD diodes have previously been incorporated on the wafers used for constructing transistor devices. For example, a portion of a semiconductor surface (e.g., a wafer or die) is used to form ESD diodes, which can be connected to transistors formed over another portion of the semiconductor surface. Thus, the ESD diodes consume a portion of the surface area, so that the portion cannot be used for transistors. In some cases, transistors are formed over one side of a wafer (e.g., the front side of a semiconductor wafer), and ESD diodes are formed on the opposite side (e.g., the back side of the semiconductor wafer). However, this requires connections between the front and back side, and may result in a thicker device than desired.

As disclosed herein, diodes, such as ESD devices, may be included in a metallization stack of an IC device. Including diodes in the metallization stack preserves more of the semiconductor surface area for transistors or other semiconductor-based devices compared to prior ESD diode integrations. The ESD diodes in the metallization stack may be fabricated using existing thin-film processes. The diodes may be sized and shaped to fit in the metallization layers, and placed to fit between routing structures in the metal layers. The sizes and materials of the diodes may be selected to provide device characteristics (e.g., forward voltage) based on the voltage level(s) of the IC device, e.g., the power supply voltage Vcc of the IC device.

An IC device includes various circuit elements, such as transistors and capacitors, coupled together by metal interconnects. The circuit elements and metal interconnects may be formed in different layers. In particular, one or more layers of an IC device in which transistors and other IC components are implemented may be referred to as a “transistor layer” or “device layer”. Layers with conductive interconnects for providing electrical connectivity (e.g., in terms of signals and power) to the transistors and/or other devices of the transistor layer of the IC device may be referred to as a “metal layer,” “metallization layer,” or “interconnect layer”. For example, the device layer may be a front-end-of-line (FEOL) layer, while the metal layers may be back-end-of-line (BEOL) layers formed over the FEOL layer. In general, the transistor layer and the metal layers may be provided in any layers of an IC device as long as they are in different planes (e.g., at different distances from) a support structure (e.g., a die, a chip, a substrate, a carrier substrate, or a package substrate) of the IC device, or some other reference plane.

Typically, an IC device includes a metallization stack, which is a collection of several metal layers, stacked above one another, in which different interconnects are provided. The interconnects include electrically conductive trenches, also referred to as lines, which provide connectivity across the layer, and electrically conductive vias (or, simply, “vias”) that provide electrical connectivity between different layers. In general, the term “trench” or “line” may be used to describe an electrically conductive element isolated by an insulator material (e.g., an insulator material typically comprising a low-k dielectric) that is provided in a plane parallel to the plane of an IC die/chip or a support structure over which an IC structure is provided, while the term “via” may be used to describe an electrically conductive element that interconnects two or more trenches of different levels of a metallization stack, or a component of the transistor layer and one or more trenches of a metallization layer. To that end, a via may be provided substantially perpendicularly to the plane of an IC die/chip or a support structure over which an IC structure is provided, and the via may interconnect two trenches in adjacent levels, two trenches in not adjacent levels, and/or a component of a transistor layer and a trench in adjacent or not adjacent layers. Sometimes, trenches and vias may be referred to as “metal trenches/tracks/lines/traces” and “metal vias”, respectively, to highlight the fact that these elements include electrically conductive materials such as, but not limited to, metals. Together, trenches and vias may be referred to as “interconnects,” “interconnect structures,” or “conductive structures,” where these terms may be used to describe any element formed of an electrically conductive material for providing electrical connectivity to/from one or more components associated with an IC or/and between various such components.

As disclosed herein, one or more diodes are included within one or more layers of a metallization stack. A diode is a two-terminal device that conducts current in one direction, referred to as the forward direction, while generally blocking current in the opposite direction, referred to as the reverse direction. In the forward direction, current enters through one terminal, which is called the anode, and leaves through the other terminal, which is called the cathode. When at least a minimum voltage, referred to as a forward voltage, is applied to the anode, this turns on the diode and current flows across the diode in the forward direction, from the anode to the cathode. Different types of materials may be used to form a diode. A semiconductor diode includes a p-n junction, which is an interface between two types of semiconductor materials, p-type and n-type. Semiconductor diodes may include silicon, germanium, compounds including silicon and/or germanium, or other types of semiconductor materials.

A Schottky diode is a different type of diode that includes a Schottky barrier. A Schottky barrier is a potential energy barrier for electrons that is formed at a metal-semiconductor junction, and a Schottky diode is a diode that includes a metal-semiconductor interface that forms a Schottky barrier. The combination of the metal and semiconductor are selected to produce a diode having a desired forward voltage. Compared to semiconductor diodes, Schottky diodes generally have a lower forward voltage drop, less leakage current, and greater temperature stability.

While a Schottky diode has a semiconductor between metal terminals, a metal-insulator-metal (MIM) diode has a thin layer of an insulator between two metal plates. The MIM diode operation may be governed by quantum tunneling (probabilistic tunneling of an electron through the insulator layer governed by quantum mechanics) or thermal activation.

In embodiments described herein, a diode, such as a Schottky diode, MIM diode, or semiconductor diode, is formed in the same layer as a set of vias. The diode includes two metal plates, e.g., the anode and the cathode, and one or more other materials, e.g., a semiconductor, a semiconductor stack, or an insulator, is sandwiched between the plates. The plates may be within different planes of the metal layer. One via is coupled to one or more transistor devices, and the other via is coupled to a ground. In an ESD event, the voltage at the anode may exceed the forward voltage, turning on the diode and sending the current to the ground, thus protecting the transistor devices. In normal operations (e.g., when there is no ESD event), the diode is turned off. The diode may be formed within a metal layer using thin film fabrication techniques, e.g., forming a first metal thin film, followed by a semiconductor thin film or insulator thin film, and then another metal thin film. Including ESD diodes within the metallization stack frees up area in the device layer and/or reduces the size of the device layer.

The metal layers with ESD diodes described herein may be implemented in combination with one or more components associated with an IC. In various embodiments, components associated with an IC include, for example, transistors, diodes, power sources, resistors, capacitors, inductors, sensors, transceivers, receivers, antennas, etc. Components associated with an IC may include those that are mounted on an IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

For purposes of explanation, specific numbers, materials and configurations are set forth in order to provide a thorough understanding of the illustrative implementations. However, it will be apparent to one skilled in the art that the present disclosure may be practiced without the specific details and/or that the present disclosure may be practiced with only some of the described aspects. In other instances, well known features are omitted or simplified in order not to obscure the illustrative implementations.

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. The meaning of “a,” “an,” and “the” include plural references. The meaning of “in” includes “in” and “on.”

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. The terms “substantially,” “close,” “approximately,” “near,” and “about,” generally refer to being within +/−20% of a target value, unless specified otherwise. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, various aspects of the illustrative implementations will be described using terms commonly employed by those skilled in the art to convey the substance of their work to others skilled in the art. For example, as used herein, a “logic state” of a ferroelectric memory cell refers to one of a finite number of states that the cell can have, e.g., logic states “1” and “0,” each state represented by a different polarization of the ferroelectric material of the cell. In another example, as used herein, a “READ” and “WRITE” memory access or operations refer to, respectively, determining/sensing a logic state of a memory cell and programming/setting a logic state of a memory cell. In other examples, the term “connected” means a direct electrical or magnetic connection between the things that are connected, without any intermediary devices, while the term “coupled” means either a direct electrical or magnetic connection between the things that are connected or an indirect connection through one or more passive or active intermediary devices. The term “circuit” means one or more passive and/or active components that are arranged to cooperate with one another to provide a desired function. In yet another example, a “high-k dielectric” refers to a material having a higher dielectric constant (k) than silicon oxide. The terms “oxide,” “carbide,” “nitride,” etc. refer to compounds containing, respectively, oxygen, carbon, nitrogen, etc.

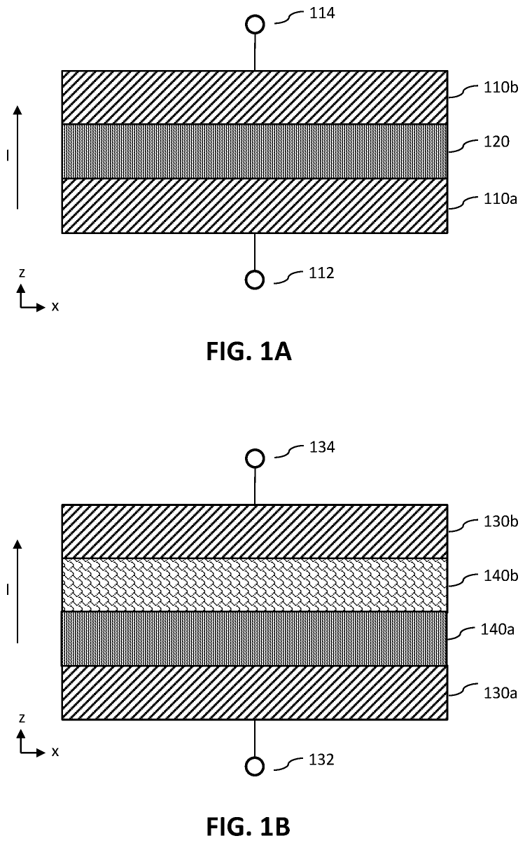

For convenience, if a collection of drawings designated with different letters are present, e.g., FIGS. 1A-1B, such a collection may be referred to herein without the letters, e.g., as “FIG. 1.”

### Example ESD Diode

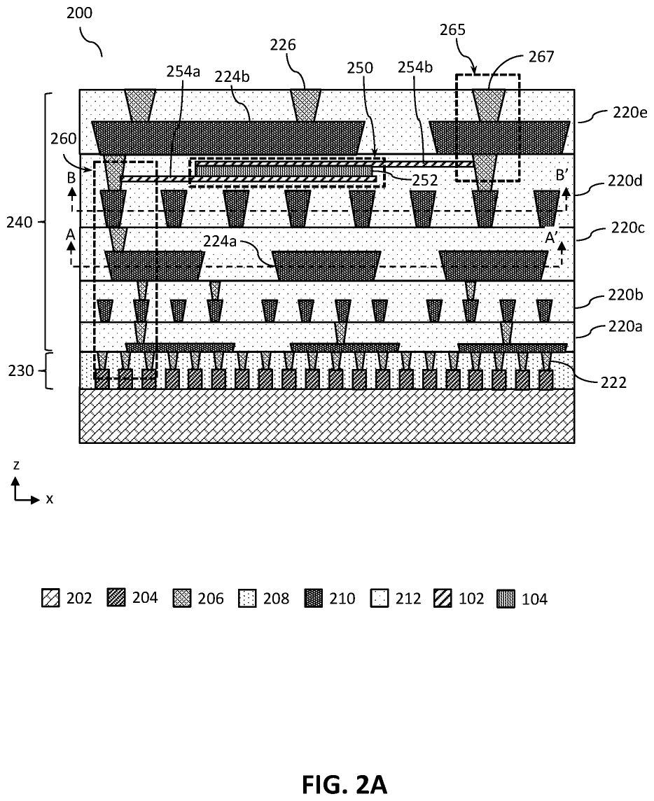

FIGS. 1A and 1B illustrate two example cross-sections of a diode that may be used for mitigating ESD events, according to some embodiments of the present disclosure. The diodes may be included in a metallization stack of an IC device, as shown in FIGS. 2-5. A number of elements referred to in the description of FIGS. 1-5 with reference numerals are illustrated in these figures with different patterns, with a legend showing the correspondence between the reference numerals and patterns being provided at the bottom of the drawing pages. For example, the legend in FIG. 1 illustrates that FIG. 1 uses different patterns to show a conductor 102, an inner material 104, and a second inner material 106.

Turning first to FIG. 1A, the diode includes two layers 110a and 110b of the conductor 102 and a layer 120 of the inner material 104. The inner material 104 may be a semiconductor if the diode is a Schottky diode. Alternatively, the inner material 104 may be an insulator if the diode is a MIM diode. The layers 110a and 110b are generally referred to as metal layers, and the layer 120 is generally referred to as the inner layer or middle layer. Two terminals 112 and 114 are represented on the metal layers 110a and 110b; in this case, the terminal 112 is the anode, and the terminal 114 is the cathode. The forward direction, from the anode 112 to the cathode 114, is indicated by the arrow labelled I.

The conductor 102 may include one or more metals, e.g., one or more of titanium, tantalum, and aluminum. For example, the conductor 102 may be a combination of two or more of titanium, tantalum, nitrogen, and aluminum, e.g., the conductor 102 may be titanium nitride, tantalum nitride, titanium aluminum nitride, or tantalum aluminum nitride.

In some embodiments, the conductor 102 and the inner material 104 are selected to produce a Schottky barrier between the metal layer 110a and the inner layer 120. The conductor 102 may include any of the materials noted above, where the combination of the conductor 102 and the inner material 104 form a Schottky barrier. In such embodiments, the inner material 104 is a semiconductor. The inner material 104 may be a semiconductor material that is suitable for depositing as a thin film. The inner material may include, for example, one or more of indium, gallium, tin, zinc, antimony, copper, nickel, niobium, titanium, and oxygen. For example, the inner material 104 may be a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. Further examples include cobalt oxide, copper oxide, nickel oxide, niobium oxide, copper peroxide, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphide, and black phosphorus, each of which may possibly be doped with one or more of gallium, indium, aluminum, fluorine, boron, phosphorus, arsenic, nitrogen, tantalum, tungsten, and magnesium, etc.

In other embodiments, the conductor 102 and inner material 104 are selected to produce a MIM diode. In a MIM diode, in some cases, electrons can tunnel from the metal layer 110a to the metal layer 110b when the voltage difference between the metal layers 110a and 110b exceeds the forward voltage. In some embodiments, the inner material 104 is an insulator that includes oxygen (e.g., an insulating oxide) and/or nitrogen (e.g., an insulating nitride). The inner material 104 may include a metal in combination with the oxygen or nitrogen, e.g., hafnium, titanium, tantalum, or nickel, to form an insulator. For example, the insulator may include hafnium oxide, titanium oxide, tantalum oxide, nickel oxide, or silicon nitride. The conductor 102 may include any of the materials noted above, where the combination of the conductor 102 and the inner material 104 form a MIM diode.

In this illustration, the metal layers 110a and 110b include the same conductor 102. In this case, the diode may be symmetrical, e.g., with the same voltage response in the forward direction and reverse direction. In other embodiments, the metal layers 110a and 110b may be different conductors, forming an asymmetric device. For example, if different conductors are used for the metal layers 110a and 110b, a Schottky barrier may be formed between the metal layer 110a and the inner layer 120 (here, a semiconductor layer), but not between the metal layer 110b and the semiconductor layer.

Each of the layers 110a, 110b, and 120 is generally relatively thin, e.g., less than 10 microns, less than 5 microns, less than 3 microns, less than 1 micron in the z-direction of the coordinate system shown. In some embodiments, the inner layer 120 has a thickness of less than 1 micron, less than 500 nanometers, less than 100 nanometers, or less than 50 nanometers, or in a range of 5 to 100 nanometers, 5 to 20 nanometers, 1 and 10 nanometers, etc. For a MIM diode, the inner layer 120 may be thin enough for quantum tunneling to occur, e.g., less than 25 nanometers, less than 15 nanometers, less than 10 nanometers, less than 5 nanometers, less than 1 nanometer, or less than 500 Angstroms.

FIG. 1B illustrates a diode that includes multiple layers of inner material. In the example of FIG. 1B, the diode includes two metal layers 130a and 130b of the conductor 102, a first inner layer 140a of the inner material 104 over the metal layer 130b, and a second inner layer 140b of the inner material 106 over the first inner layer 140a and under the second metal layer 130b. In other examples, one or more additional layers may be included.

In some examples, one of the inner materials 104 or 106 is a semiconductor, and one of the inner materials 104 or 106 is an insulator, e.g., any of the insulators or semiconductors described above. Alternatively, both inner materials 104 and 106 may be inductors, or both may be semiconductors. In some embodiments, in the direction of current flow (i.e., the forward direction), the wider bandgap material is positioned first, e.g., as the inner layer 140a in FIG. 1B, while the narrower bandgap material is positioned second, e.g., as the inner layer 140b in FIG. 1B.

In some examples, the inner materials 104 or 106 are semiconductor materials with different carrier types, i.e., one is a p-type semiconductor and the other is an n-type semiconductor. In conductor and semiconductor materials, a charge carrier is a particle or quasiparticle that can move within the material, carrying a conductive charge and resulting in a net motion of particles through the material. In some semiconductors, the main charge carriers are electrons, while in others, the main charge carriers are electron holes (i.e., electron vacancies), generally referred to as holes. A semiconductor material or semiconductor region with holes as the primary charge carrier is referred to as p-type, and a semiconductor material or semiconductor region with electrons as the primary charge carrier is referred to as n-type. Doping may be used to create a p-type or n-type material; for example, silicon can be doped such that it is either n-type or p-type. Having an opposite charge carrier one portion of the diode (e.g., the first inner layer 140a) compared to another portion of the diode (e.g., the second inner layer 140b) can create a p-n junction.

The inner materials 104 and 106 may include any of the semiconductor materials described above. For example, suitable p-type semiconductor materials include p-type metal oxides that include oxygen in combination with titanium, copper, nickel, and/or niobium. Suitable n-type materials include, for example, various combinations of indium, gallium, zinc, and/or tin, optionally with oxygen, and may include materials such as tin oxide, indium oxide, indium tin oxide, zinc oxide, indium zinc oxide, indium gallium zinc oxide (IGZO), gallium oxide, ruthenium oxide, or tungsten oxide.

The diode of FIG. 1B may further have a bulk semiconductor region between the first inner layer 140a and the second inner layer 140b, or one of the first inner layer 140a and 140b may include a lower-doped portion (functioning as a bulk semiconductor region) near the junction between the first inner layer 140a and 140b and a higher-doped portion nearer to one of the metal layers 130a or 130b. A bulk semiconductor region may have a relatively low level of a dopant, which is a same type of dopant as one of the inner materials 104 or 106, but at a lower level. For example, the first inner material 104 is a highly-doped n-type material, the bulk semiconductor material is a lower-doped n-type material, and the second inner material 106 is a p-type material. The bulk semiconductor region can provide mechanical support to a diode structure, as well as electrical isolation between two more highly-doped regions. Additionally, the bulk semiconductor region can help prevent the depletion region, which forms at the junction of the p-type and n-type materials when the diode is biased, from extending across the diode and causing unwanted leakage currents.

In FIG. 1B, the metal layers 130a and 130b include the same conductor 102. In other embodiments, the metal layers 130a and 130b may include different materials, as described with respect to FIG. 1A. The thickness of the layers 130a, 130b, 140a, and 140b may be similar to the thickness described with respect to the layers 110 and 120.

Example IC device with device layer and metal layers

FIGS. 2A-2C illustrate different cross sections of an IC device 200 having a device layer and multiple metal layers, according to some embodiments of the present disclosure. The diode described herein (e.g., the diode of FIG. 1A or 1B) may be included in one or more of the metal layers. FIG. 2A provides a first cross-section in an x-z plane. FIGS. 2B and 2C provide two cross-sections through the x-y plane. FIG. 2B is a cross-section through the plane AA′ in FIG. 2A, and FIG. 2C is a cross-section through the plane BB′ in FIG. 2A.

As noted above, elements referred to in the description of FIGS. 2A-2C are illustrated in these figures with different patterns, with a legend showing the correspondence between the reference numerals and patterns being provided at the bottom of the drawing pages. The legend in FIG. 2 illustrates that FIG. 2 uses different patterns to show the conductor 102, the inner material 104, a support structure 202, logic devices 204, a first conductive material 206, a first dielectric material 208, a second conductive material 210, and a second dielectric material 212.

FIG. 2A illustrates cross sections of a device layer 230 and a metallization stack 240. The device layer 230 is over a support structure 202. In this example, the device layer 230 includes logic devices 204, e.g., transistors. In some embodiments, the logic devices 204, or a portion of the logic devices 204, are logic transistors in a compute logic layer or compute logic region. In some embodiments, the logic devices 204, or a portion of the logic devices, are access transistors in a memory layer, e.g., transistors that provide access to capacitor-based memory. In some embodiments, the logic devices 204 may provide transistor-based memory, such as static random-access memory (SRAM), which uses transistors arranged as latches, also referred to as flip-flops, to store data. In some embodiments, the device layer 230 and/or additional layers above or below the device layer 230 may include additional or alternative types of devices, such as capacitors, inductors, waveguides, etc.

The logic devices 204 may include a wide variety of configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors. As shown in FIG. 2A, at least a portion of the logic devices 204 may be coupled to interconnect structures in the metallization stack 240. For example, the logic devices 204 may be semiconductor devices (e.g., transistors) coupled to contacts formed from the first conductive material 206 (e.g., source, drain, and/or gate contacts). The via 222 is an example of a contact to a logic device 204.

The metallization stack 240 includes multiple metal layers 220a-220e, where 220a is the lowermost metal layer over the device layer 230, and the metal layer 220e is the uppermost metal layer. While five metal layers 220a, 220b, 220c, 220d, and 220e are illustrated in FIG. 2A, an IC device may have fewer or more metal layers, e.g., up to 10 metal layers, up to 15 metal layers, or more. In addition, while metal layers 220 are on one side of the device layer 230, in other embodiments, metal layers may be included on both sides of the device layer 230, e.g., on the front side and the back side.

Each metal layer 220 includes conductive structures, including metal lines or trenches (e.g., the lines 224a and 224b) formed from the second conductive material 210 and vias (e.g., the via 226) formed from the first conductive material 206. In general, interconnect structures, e.g., vias and metal lines, are referred to herein as conductive structures. While FIG. 2 illustrates a first conductive material 206 for the vias and a second conductive material 210 for the metal lines, at each metal layer, any suitable conductive material may be used. For example, in a given layer, the same conductive material may be used for both metal lines and vias. As another example, in different layers, different materials may be used for the metal lines and/or vias, e.g., ruthenium may be included in the metal lines in the metal layer 220a, while copper is included in the metal lines in the metal layer 220d. In various embodiments, conductive structures may include multiple conductive materials, e.g., a first metal as a liner, and a second metal as a fill.

The logic devices 204 are surrounded by a first dielectric material 208 in the device layer 230. The metal lines and vias in the metal layers 220a-220e are surrounded by a second dielectric material 212. In some embodiments, the dielectric materials 208 and 212 may be the same. In some embodiments, different dielectric materials may be included in different ones of the metal layers, e.g., the metal layer 220a may include a different dielectric material from the metal layer 220d. In some embodiments, multiple dielectric materials may be present in a given layer.

More generally, the dielectric materials 208 and 212 may include low-k or high-k dielectrics including, but not limited to, elements such as hafnium, silicon, oxygen, nitrogen, titanium, tantalum, lanthanum, aluminum, zirconium, barium, strontium, yttrium, lead, scandium, niobium, and zinc. Further examples of dielectric materials include, but are not limited to silicon nitride, silicon oxide, silicon dioxide, silicon carbide, silicon nitride doped with carbon, silicon oxynitride, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate.

In addition, the conductive materials 206 and 210 may include one or more metals or metal alloys, with materials such as copper, ruthenium, palladium, platinum, cobalt, nickel, hafnium, zirconium, titanium, tantalum, and aluminum, tantalum nitride, tungsten, doped silicon, doped germanium, or alloys and mixtures of any of these. In some embodiments, conductive materials 206 and 210 may include one or more electrically conductive alloys, oxides, or carbides of one or more metals. The conductive materials 206 and 210 may form conductive pathways to route power, ground, and/or signals to/from various components of the logic layer 230. The arrangement of the conductive materials 206 and 210 in FIG. 2 is merely illustrative, and the conductive pathways formed by the conductive materials 206 and 210 may be connected to one another in any suitable manner.

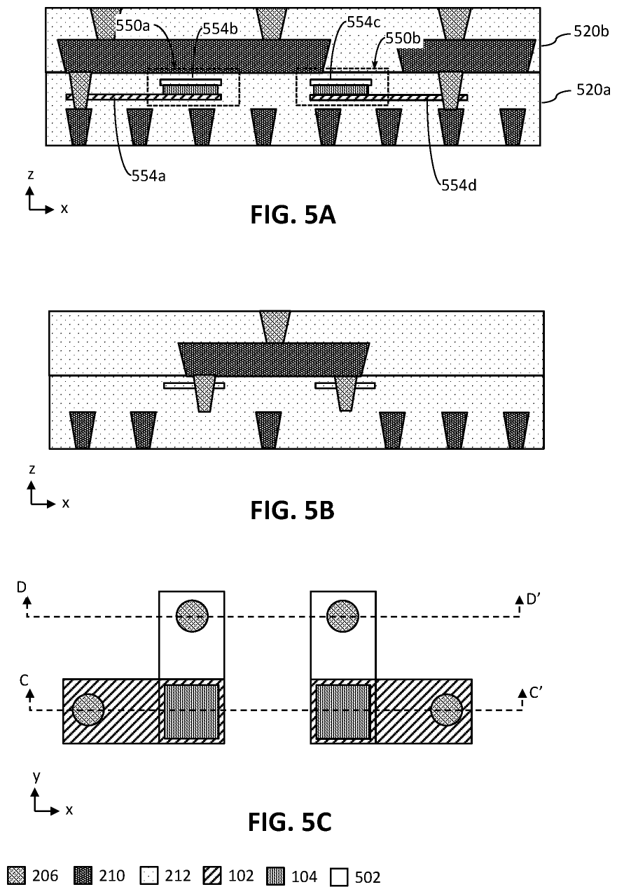

One or more of the metal layers 220 may include one or more diodes. In this example, the metal layer 220d (e.g., metal layer M3) includes a diode 250, which is an example of the diode described with respect to FIG. 1A. The diode 250 includes an inner layer 252, which corresponds to the inner layer 120, and two metal plates 254a and 254b, which correspond to the metal layers 110a and 110b, respectively. The inner layer 252 may include one or more insulator layers, one or more semiconductor layers, or both an insulator layer and a semiconductor layer, as described above. For example, the diode 250 may include two different semiconductor layers, as shown in FIG. 1B. In some embodiments, each of the metal plates 254a and 254b extends primarily in the x-direction in the coordinate system shown, e.g., the metal plates 254a and 254b may have a longest dimension extending in the x-direction. In some cases, the metal plate of a diode may extend in perpendicular directions, e.g., as shown in FIG. 5, described below. The diode 250, including the inner layer 252, may have a rectangular or square cross-section in the x-y plane, or the cross-section through the x-y plane may have some other shape (e.g., circular, oval, triangle, etc.).

The diode 250 is a stack that includes the metal plate 254a, inner layer 252, and metal plate 254b. The inner layer 252 is over a portion of the metal plate 254a, and a portion of the metal plate 254b is over the inner layer 252 and a portion of the metal plate 254a. The diode 250 is within the second dielectric material 212 of the metal layer 220d, with the metal plate 254a and 254b each coupled to a respective via within the metal layer 220d.

The metal plate 254a, which is the anode, is coupled to the device layer 230, e.g., via a set of vias and trenches in the box 260. In particular, the conductive structures in the box 260 electrically couple the metal plate 254a to one or more logic devices 204, e.g., one or more transistors. The metal plate 254b, which is the cathode, is coupled to a ground. For example, the metal plate 254b is coupled to the set of vias and trenches in the box 265, and the uppermost via 267 in the metal layer 220e may be coupled to an electrical ground. For illustration, the routes to the device layer 230 and ground illustrated in the boxes 260 and 265 are visible within the cross section, but in other embodiments, the routing may not be visible in a single cross-section, e.g., the route may not travel through a single x-z plane.

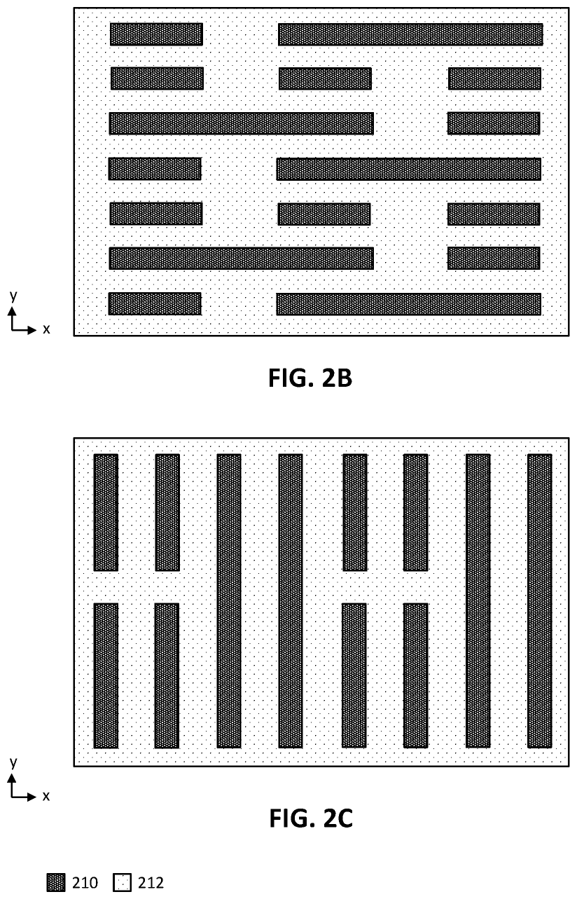

While the diode 250 is included in the metal layer 220d, in other examples, one or more diodes may be included in different metal layers of the IC device 200. In some embodiments, multiple diodes are included in an IC device, e.g., one or more diodes within different metal layers, and/or multiple diodes within a single metal layer. Additional examples of diodes that may be included in a metallization stack are illustrated in FIGS. 3-5.

The support structure 202 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. Although a few examples of materials from which the support structure 202 may be formed are described here, any material that may serve as a foundation upon which an IC device as described herein may be built falls within the spirit and scope of the present disclosure.

FIGS. 2B and 2C illustrate cross-sections through two example metal layers 220c and 220d. The metal lines in a given metal layer are generally elongated structures that extend primarily in one direction within the metal layer. Typically, this direction is substantially parallel to the or perpendicular to the arrangement of the logic devices in the device layer 230, and is either perpendicular or parallel to different edges of the support structure 202, in particular, being either perpendicular or parallel to different edges of the front face or the back face of the support structure. At different metal layers 220, the metal lines may extend in different directions. For example, in the metal layer 220c, the metal lines extend in the x-direction in the coordinate system shown in FIG. 2, as illustrated in FIG. 2B. In the metal layer 220d, the metal lines extend in the y-direction in the coordinate system shown in FIG. 2 (i.e., perpendicular to the metal lines in metal layer 220c), as illustrated in FIG. 2C.

### Example Embodiments of Diodes in Metal Layers

FIG. 3 is a cross-section of another embodiment of a diode that may be included in a metal layer, according to some embodiments of the present disclosure. FIG. 3 illustrates two metal layers 320a and 320b, which may be similar to any two of the metal layers 220 of FIG. 2. FIG. 3 includes a diode 350 within the metal layer 320a. The diode 350 includes an inner layer 352, which corresponds to the inner layer 120, and two metal plates 354a and 354b, which correspond to the metal layers 110a and 110b, respectively. In other embodiments, the diode 350 may have multiple inner layers which may include different materials (e.g., the inner materials 104 and 106), as described with respect to FIG. 1B. The diode 350 is similar to the diode 250, described above, except that the diode 350 has a smaller width in the x-direction compared to the diode 250. While the width of the diode 250 extended across much of the distance between the two vias coupled to the metal plates 254a and 254b, in the example of FIG. 3, the diode 350 is narrower, e.g., the lower metal plate 354a and the inner layer 352 do not extend as far to the right in the orientation shown.

The size and shape of the diode may be tuned to achieve particular device properties, e.g., for a particular forward voltage. To obtain a diode with a given forward voltage, a device with a smaller cross-sectional area (i.e., an area in the x-y plane) may be thicker in the z-direction, e.g., the inner layer 120 or inner layers 140 and 142 may be thicker. However, a thicker inner layer may be more prone to defects. Thus, it may be advantageous for the diode 350 to be relatively smaller and thinner than the diode 250. In addition, it may be easier to fit the diode 350 among routing structures, e.g., vias in the metal layer 320a that are within different x-z planes.

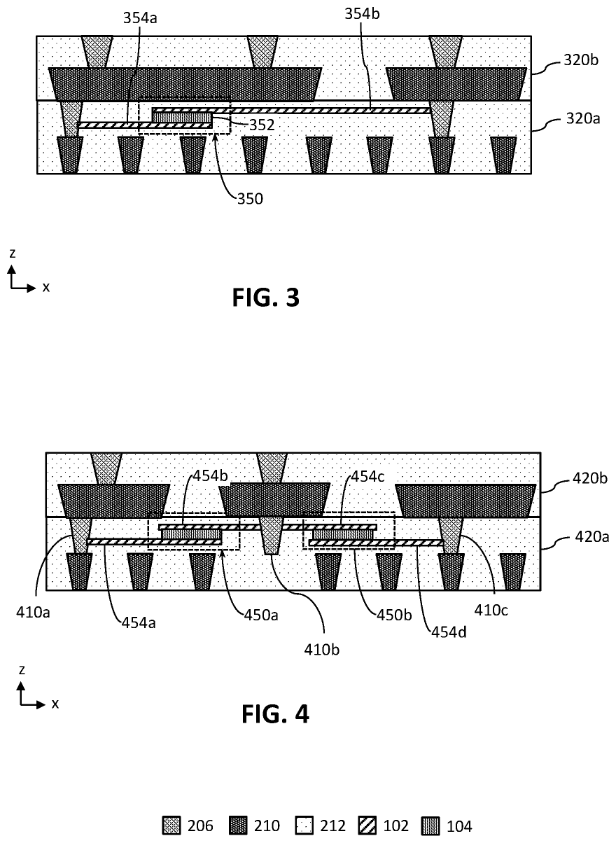

FIG. 4 is a cross-section of a set of diodes that may be included in a metal layer, according to some embodiments of the present disclosure. FIG. 4 illustrates two metal layers 420a and 420b, which may be similar to any two of the metal layers 220 of FIG. 2. FIG. 4 includes two diodes 450a and 450b within the metal layer 320a. Each of the diodes 450a and 450b includes an inner layer, which is similar to the inner layers 120, 252, and 352, and two metal plates, which are similar to the metal layers 110, 254, and 354 respectively. The diodes 450 are similar to the diode 350, described above. In other embodiments, the diodes 450 may have multiple inner layers which may include different materials (e.g., the inner materials 104 and 106), as described with respect to FIG. 1B.

In this example, each diode 450a and 450b may be coupled to a different portion of a device layer (not shown in FIG. 4). For example, the diode 450a includes a metal plate 454a that is coupled to a via 410a; this via 410a may be electrically coupled (via one or more additional conductive structures in the metallization stack) to a transistor or set of transistors. The diode 450b includes a metal plate 454d that is coupled to another via 410c; this via 450c may be electrically coupled (via one or more additional conductive structures in the metallization stack) to a different transistor or different set of transistors.

In this example, the diode 450a has a metal plate 454b that is coupled to a via 410b, which may be coupled to an electrical ground, in a similar manner to the pathway in the box 265 of FIG. 2. The diode 450b has a metal plate 450c that is also coupled to the via 410b, thus coupling the cathode of the diode 450b to the electrical ground. In other embodiments, the cathode metal plates 454b and 454c may be coupled to different vias which are coupled to a ground in a higher metal layer, for example.

In FIGS. 2-4, each of the metal plates extend primarily in the x-direction in the coordinate system shown. In other embodiments, metal plates within a given diode, or within different diodes, may extend primarily in a perpendicular direction. Changing the direction of the plates may permit different routing arrangements to transistors and/or to ground.

FIGS. 5A-5C illustrate two cross-sections of a set of diodes in a metal layer and a top-down illustration of the diodes, according to some embodiments of the present disclosure. FIGS. 5A and 5B illustrate two cross-sections through metal layers 520a and 520b, which may be similar to any two of the metal layers 220 of FIG. 2. FIG. 5A illustrates two diodes 550a and 550b within the metal layer 520a. Each of the diodes 550a and 550b includes an inner layer, which is similar to the inner layers 120, 252, 352, and 452, and two metal plates, which are similar to the metal layers 110, 254, 354, and 454, respectively. In other embodiments, the diodes 550 may have multiple inner layers which may include different materials (e.g., the inner materials 104 and 106), as described with respect to FIG. 1B. In FIG. 5, the upper metal plates 554b and 554c are drawn using the pattern 502, which is a transparent box with a black border, so that in the top-down view in FIG. 5C, lower layers are visible. The pattern 502 may be any conductor, e.g., the same as the conductor 102.

The lower metal plates 554a and 554d are similar to the metal plates 454a and 454d. Like the metal plates 454a and 454d of FIG. 4, the metal plates 554a and 554d extend primarily in the x-direction, as shown in FIGS. 5A and 5C. The upper metal plates 554b and 554c extend primarily in the y-direction, i.e., in a direction perpendicular to the metal plates 554a and 554d.

FIG. 5A shows a cross-section of the metal plates 554b and 554c in an area over the inner layer, e.g., where the diodes 550a and 550b are formed. FIG. 5B shows a cross-section through the metal plates 554b and 554c at a different position in the y-direction. FIG. 5C shows a top-down view of only the diodes 550a and 550b, including the full metal plates 554a-554d. FIG. 5A is a cross-section through the plane CC′ in FIG. 5C, and FIG. 5B is a cross-section through the plane DD′ in FIG. 5C.

FIG. 5C further illustrates that the metal plates 554a and 554b primarily extend (e.g., have a longest dimension) in two perpendicular directions, and the inner layer is between the overlapping portions of the metal plates 554a and 554b. While the inner layer is illustrated as having a smaller footprint than the overlap of the metal plates 554a and 554b, in other embodiments, the inner layer has the same footprint as the overlap of the metal plates 554a and 554b, or a greater footprint.

Likewise, the metal plates 554c and 554d also primarily extend (e.g., have a longest dimension) in two perpendicular directions, and the inner layer of the diode 550b is between the overlapping portions of the metal plates 554c and 554d. The inner layer of the diode 550b may also have a different footprint, as described with respect to the diode 550a.

In some embodiments, the diodes 550 may have a footprint, i.e., an area in the x-y direction, of around 50 microns to 5000 microns. For example, the diodes 550 may have a width and length in the x-direction and y-direction, respectively, of 10 microns×10 microns, or 50 microns×50 microns. These sizes are examples, and the diodes described herein may have different shapes or sizes, e.g., rectangular, circular, etc.

### Example Devices

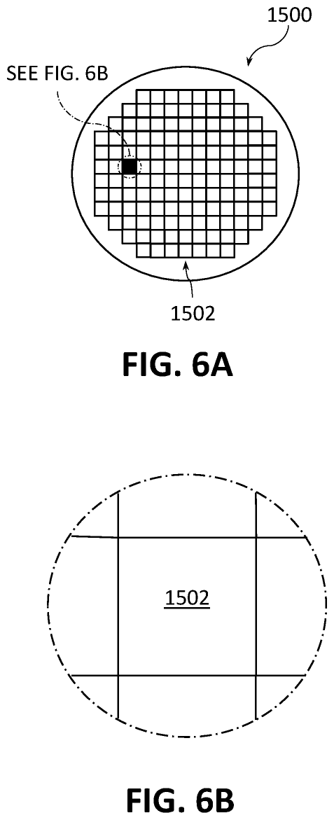

The circuit devices with one or more metal layers with at least one diode disclosed herein may be included in any suitable electronic device. FIGS. 6-9 illustrate various examples of apparatuses that may include the one or more transistors disclosed herein, which may have been fabricated using the processes disclosed herein.

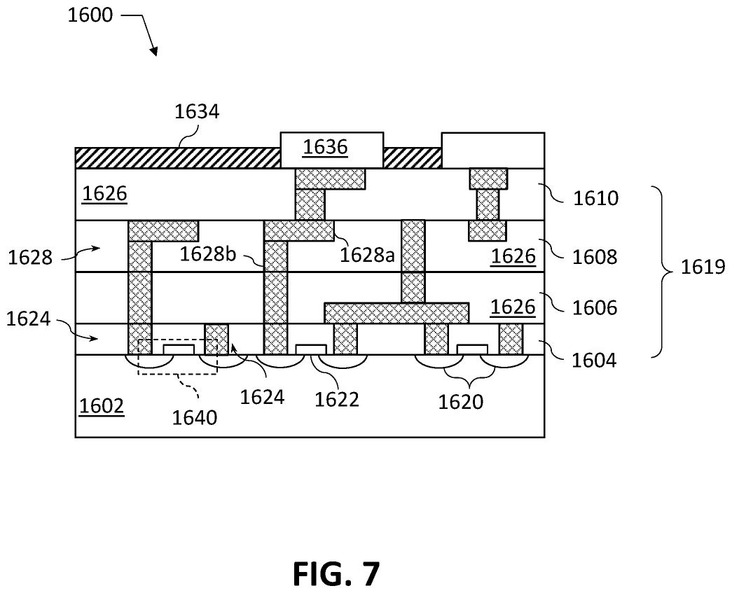

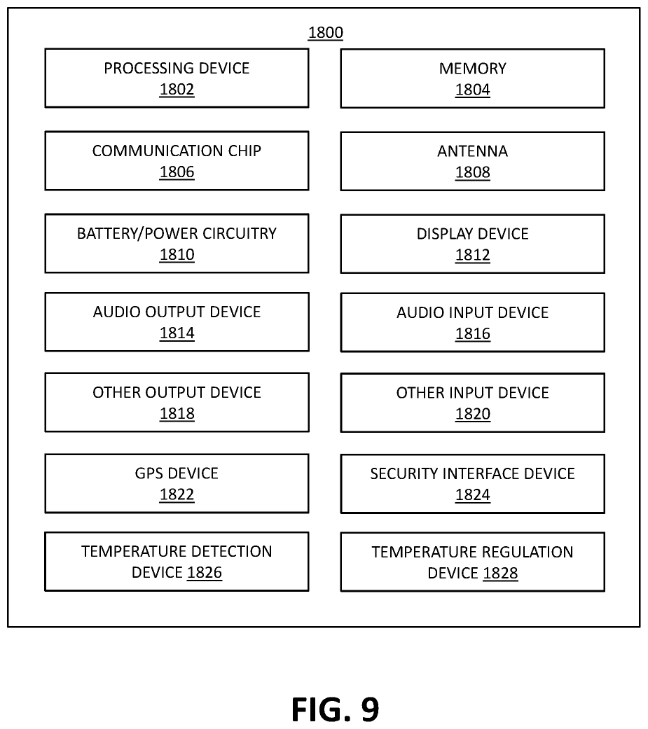

FIGS. 6A and 6B are top views of a wafer and dies that include one or more IC structures including one or more metal layers with at least one diode in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC structure (e.g., the IC structures as shown in any of FIGS. 3-10, or any further embodiments of the IC structures described herein). After the fabrication of the semiconductor product is complete (e.g., after manufacture of one or more IC structures with one or more of the transistors as described herein, included in a particular electronic component, e.g., in a transistor or in a memory device), the wafer 1500 may undergo a singulation process in which each of the dies 1502 is separated from one another to provide discrete “chips” of the semiconductor product. In particular, devices that include one or more of the transistors as disclosed herein may take the form of the wafer 1500 (e.g., not singulated) or the form of the die 1502 (e.g., singulated). The die 1502 may include one or more transistors (e.g., one or more of the transistors 1640 of FIG. 7, discussed below) and/or supporting circuitry to route electrical signals to the transistors, as well as any other IC components (e.g., one or more of the non-planar transistors described herein). In some embodiments, the wafer 1500 or the die 1502 may include a memory device (e.g., an SRAM device), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 9) or other logic that is configured to store information in the memory devices or execute instructions stored in the memory array.

FIG. 7 is a cross-sectional side view of an IC device 1600 that may include one or more metal layers with at least one diode in accordance with any of the embodiments disclosed herein. The IC device 1600 may be formed on a substrate 1602 (e.g., the wafer 1500 of FIG. 6A) and may be included in a die (e.g., the die 1502 of FIG. 6B). The substrate 1602 may be any substrate as described herein. The substrate 1602 may be part of a singulated die (e.g., the dies 1502 of FIG. 6B) or a wafer (e.g., the wafer 1500 of FIG. 6A).

The IC device 1600 may include one or more device layers 1604 disposed on the substrate 1602. The device layer 1604 may include features of one or more transistors 1640 (e.g., metal-oxide-semiconductor field-effect transistors (MOSFETs)) formed on the substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 7 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1640 may include a gate 1622 formed of at least two layers, a gate electrode layer and a gate dielectric layer.

The gate electrode layer may be formed on the gate interconnect support layer and may consist of at least one P-type workfunction metal or N-type workfunction metal, depending on whether the transistor is to be a PMOS or an NMOS transistor, respectively. In some implementations, the gate electrode layer may consist of a stack of two or more metal layers, where one or more metal layers are workfunction metal layers and at least one metal layer is a fill metal layer. Further metal layers may be included for other purposes, such as a barrier layer or/and an adhesion layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 electron Volts (eV) and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, aluminum carbide, tungsten, tungsten carbide. An N-type metal layer will enable the formation of an NMOS gate electrode with a workfunction that is between about 3.9 eV and about 4.2 eV.

In some embodiments, when viewed as a cross-section of the transistor 1640 along the source-channel-drain direction, the gate electrode may be formed as a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may be implemented as a combination of U-shaped structures and planar, non-U-shaped structures. For example, the gate electrode may be implemented as one or more U-shaped metal layers formed atop one or more planar, non-U-shaped layers. In some embodiments, the gate electrode may consist of a V-shaped structure (e.g., when a fin of a FinFET transistor does not have a “flat” upper surface, but instead has a rounded peak).

Generally, the gate dielectric layer of a transistor 1640 may include one layer or a stack of layers, and the one or more layers may include silicon oxide, silicon dioxide, and/or a high-k dielectric material. The high-k dielectric material included in the gate dielectric layer of the transistor 1640 may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The IC device 1600 may include one or more metal layers with at least one diode at any suitable location in the IC device 1600.

The S/D regions 1620 may be formed within the substrate 1602 adjacent to the gate 1622 of each transistor 1640, using any suitable processes known in the art. For example, the S/D regions 1620 may be formed using either an implantation/diffusion process or a deposition process. In the former process, dopants such as boron, aluminum, antimony, phosphorous, or arsenic may be ion-implanted into the substrate 1602 to form the S/D regions 1620. An annealing process that activates the dopants and causes them to diffuse farther into the substrate 1602 may follow the ion implantation process. In the latter process, an epitaxial deposition process may provide material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620. In some embodiments, an etch process may be performed before the epitaxial deposition to create recesses in the substrate 1602 in which the material for the S/D regions 1620 is deposited.

Electrical signals, such as power and/or input/output (I/O) signals, may be routed to and/or from the transistors 1640 of the device layer 1604 through one or more interconnect layers disposed on the device layer 1604 (illustrated in FIG. 7 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form an ILD stack 1619 of the IC device 1600.

The interconnect structures 1628 may be arranged within the interconnect layers 1606-1610 to route electrical signals according to a wide variety of designs (in particular, the arrangement is not limited to the particular configuration of interconnect structures 1628 depicted in FIG. 7). Although a particular number of interconnect layers 1606-1610 is depicted in FIG. 7, embodiments of the present disclosure include IC devices having more or fewer interconnect layers than depicted.

In some embodiments, the interconnect structures 1628 may include trench contact structures 1628a (sometimes referred to as “lines”) and/or via structures 1628b (sometimes referred to as “holes”) filled with an electrically conductive material such as a metal. The trench contact structures 1628a may be arranged to route electrical signals in a direction of a plane that is substantially parallel with a surface of the substrate 1602 upon which the device layer 1604 is formed. For example, the trench contact structures 1628a may route electrical signals in a direction in and out of the page from the perspective of FIG. 7. The via structures 1628b may be arranged to route electrical signals in a direction of a plane that is substantially perpendicular to the surface of the substrate 1602 upon which the device layer 1604 is formed. In some embodiments, the via structures 1628b may electrically couple trench contact structures 1628a of different interconnect layers 1606-1610 together.

The interconnect layers 1606-1610 may include a dielectric material 1626 disposed between the interconnect structures 1628, as shown in FIG. 7. The dielectric material 1626 may take the form of any of the embodiments of the dielectric material provided between the interconnects of the IC structures disclosed herein.

In some embodiments, the dielectric material 1626 disposed between the interconnect structures 1628 in different ones of the interconnect layers 1606-1610 may have different compositions. In other embodiments, the composition of the dielectric material 1626 between different interconnect layers 1606-1610 may be the same.

A first interconnect layer 1606 (referred to as Metal 1 or “M1”) may be formed directly on the device layer 1604. In some embodiments, the first interconnect layer 1606 may include trench contact structures 1628a and/or via structures 1628b, as shown. The trench contact structures 1628a of the first interconnect layer 1606 may be coupled with contacts (e.g., the S/D contacts 1624) of the device layer 1604.

A second interconnect layer 1608 (referred to as Metal 2 or “M2”) may be formed directly on the first interconnect layer 1606. In some embodiments, the second interconnect layer 1608 may include via structures 1628b to couple the trench contact structures 1628a of the second interconnect layer 1608 with the trench contact structures 1628a of the first interconnect layer 1606. Although the trench contact structures 1628a and the via structures 1628b are structurally delineated with a line within each interconnect layer (e.g., within the second interconnect layer 1608) for the sake of clarity, the trench contact structures 1628a and the via structures 1628b may be structurally and/or materially contiguous (e.g., simultaneously filled during a dual-damascene process) in some embodiments.

A third interconnect layer 1610 (referred to as Metal 3 or “M3”) (and additional interconnect layers, as desired) may be formed in succession on the second interconnect layer 1608 according to similar techniques and configurations described in connection with the second interconnect layer 1608 or the first interconnect layer 1606.

The IC device 1600 may include a solder resist material 1634 (e.g., polyimide or similar material) and one or more bond pads 1636 formed on the interconnect layers 1606-1610. The bond pads 1636 may be electrically coupled with the interconnect structures 1628 and configured to route the electrical signals of the transistor(s) 1640 to other external devices. For example, solder bonds may be formed on the one or more bond pads 1636 to mechanically and/or electrically couple a chip including the IC device 1600 with another component (e.g., a circuit board). The IC device 1600 may have other alternative configurations to route the electrical signals from the interconnect layers 1606-1610 than depicted in other embodiments. For example, the bond pads 1636 may be replaced by or may further include other analogous features (e.g., posts) that route the electrical signals to external components.

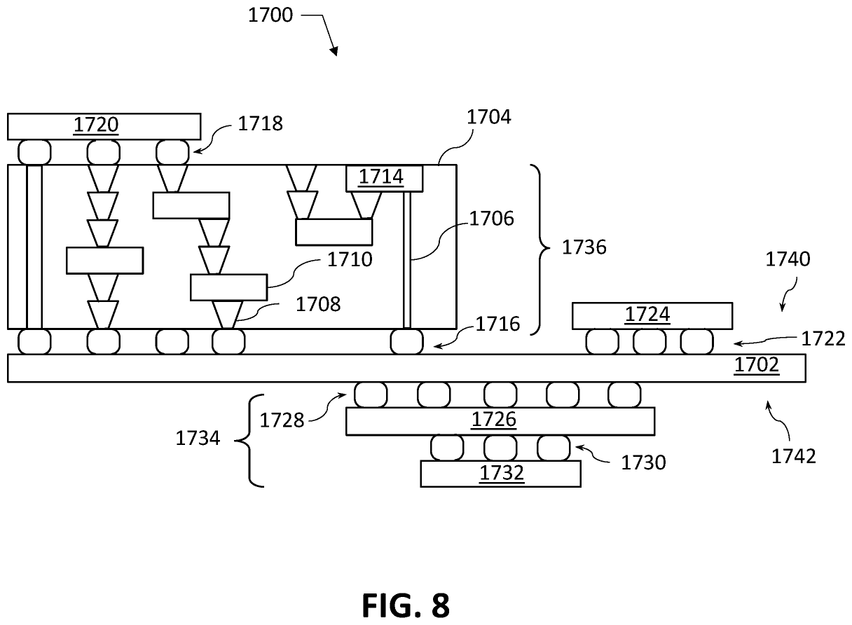

FIG. 8 is a cross-sectional side view of an IC device assembly 1700 that may include components having or being associated with (e.g., being electrically connected by means of) one or more metal layers with at least one diode in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. In particular, any suitable ones of the components of the IC device assembly 1700 may include one or more of the non-planar transistors disclosed herein.

In some embodiments, the circuit board 1702 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 8 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702 and may include solder balls (as shown in FIG. 8), male and female portions of a socket, an adhesive, an underfill material, and/or any other suitable electrical and/or mechanical coupling structure.

The package-on-interposer structure 1736 may include an IC package 1720 coupled to an interposer 1704 by coupling components 1718. The coupling components 1718 may take any suitable form for the application, such as the forms discussed above with reference to the coupling components 1716. Although a single IC package 1720 is shown in FIG. 8, multiple IC packages may be coupled to the interposer 1704; indeed, additional interposers may be coupled to the interposer 1704. The interposer 1704 may provide an intervening substrate used to bridge the circuit board 1702 and the IC package 1720. The IC package 1720 may be or include, for example, a die (the die 1502 of FIG. 6B), an IC device (e.g., the IC device 1600 of FIG. 7), or any other suitable component. In some embodiments, the IC package 1720 may include one or more metal layers with at least one diode, as described herein. Generally, the interposer 1704 may spread a connection to a wider pitch or reroute a connection to a different connection. For example, the interposer 1704 may couple the IC package 1720 (e.g., a die) to a ball grid array (BGA) of the coupling components 1716 for coupling to the circuit board 1702. In the embodiment illustrated in FIG. 8, the IC package 1720 and the circuit board 1702 are attached to opposing sides of the interposer 1704; in other embodiments, the IC package 1720 and the circuit board 1702 may be attached to a same side of the interposer 1704. In some embodiments, three or more components may be interconnected by way of the interposer 1704.

The interposer 1704 may be formed of an epoxy resin, a fiberglass-reinforced epoxy resin, a ceramic material, or a polymer material such as polyimide. In some implementations, the interposer 1704 may be formed of alternate rigid or flexible materials that may include the same materials described above for use in a semiconductor substrate, such as silicon, germanium, and other group III-V and group IV materials. The interposer 1704 may include metal interconnects 1708 and vias 1710, including but not limited to TSVs 1706. The interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency (RF) devices, power amplifiers, power management devices, antennas, arrays, sensors, and microelectromechanical systems (MEMS) devices may also be formed on the interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 8 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 9 is a block diagram of an example computing device 1800 that may include one or more metal layers with at least one diode in accordance with any of the embodiments disclosed herein. For example, any suitable ones of the components of the computing device 1800 may include a die (e.g., the die 1502 (FIG. 6B)) having one or more metal layers with at least one diode. Any one or more of the components of the computing device 1800 may include, or be included in, an IC device 1600 (FIG. 7). Any one or more of the components of the computing device 1800 may include, or be included in, an IC device assembly 1700 (FIG. 8).

A number of components are illustrated in FIG. 9 as included in the computing device 1800, but any one or more of these components may be omitted or duplicated, as suitable for the application. In some embodiments, some or all of the components included in the computing device 1800 may be attached to one or more motherboards. In some embodiments, some or all of these components are fabricated onto a single system-on-a-chip (SoC) die.

Additionally, in various embodiments, the computing device 1800 may not include one or more of the components illustrated in FIG. 9, but the computing device 1800 may include interface circuitry for coupling to the one or more components. For example, the computing device 1800 may not include a display device 1812, but may include display device interface circuitry (e.g., a connector and driver circuitry) to which a display device 1812 may be coupled. In another set of examples, the computing device 1800 may not include an audio input device 1816 or an audio output device 1814, but may include audio input or output device interface circuitry (e.g., connectors and supporting circuitry) to which an audio input device 1816 or audio output device 1814 may be coupled.

The computing device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 1800 may include a memory 1804, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random access memory (eDRAM) or spin transfer torque magnetic random-access memory (STT-MRAM).

In some embodiments, the computing device 1800 may include a communication chip 1806 (e.g., one or more communication chips). For example, the communication chip 1806 may be configured for managing wireless communications for the transfer of data to and from the computing device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1806 may implement any of a number of wireless standards or protocols, including but not limited to Institute for Electrical and Electronic Engineers (IEEE) standards including Wi-Fi (IEEE 1402.11 family), IEEE 1402.18 standards (e.g., IEEE 1402.18-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 1402.18 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.18 standards. The communication chip 1806 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1806 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1806 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1806 may operate in accordance with other wireless protocols in other embodiments. The computing device 1800 may include an antenna 1808 to facilitate wireless communications and/or to receive other wireless communications (such as AM or FM radio transmissions).

In some embodiments, the communication chip 1806 may manage wired communications, such as electrical, optical, or any other suitable communication protocols (e.g., the Ethernet). As noted above, the communication chip 1806 may include multiple communication chips. For instance, a first communication chip 1806 may be dedicated to shorter-range wireless communications such as Wi-Fi or Bluetooth, and a second communication chip 1806 may be dedicated to longer-range wireless communications such as GPS, EDGE, GPRS, CDMA, WiMAX, LTE, EV-DO, or others. In some embodiments, a first communication chip 1806 may be dedicated to wireless communications, and a second communication chip 1806 may be dedicated to wired communications.

The computing device 1800 may include a battery/power circuitry 1810. The battery/power circuitry 1810 may include one or more energy storage devices (e.g., batteries or capacitors) and/or circuitry for coupling components of the computing device 1800 to an energy source separate from the computing device 1800 (e.g., AC line power).

The computing device 1800 may include a display device 1812 (or corresponding interface circuitry, as discussed above). The display device 1812 may include any visual indicators, such as a heads-up display, a computer monitor, a projector, a touchscreen display, a liquid crystal display (LCD), a light-emitting diode display, or a flat panel display, for example.

The computing device 1800 may include an audio output device 1814 (or corresponding interface circuitry, as discussed above). The audio output device 1814 may include any device that generates an audible indicator, such as speakers, headsets, or earbuds, for example.

The computing device 1800 may include an audio input device 1816 (or corresponding interface circuitry, as discussed above). The audio input device 1816 may include any device that generates a signal representative of a sound, such as microphones, microphone arrays, or digital instruments (e.g., instruments having a musical instrument digital interface (MIDI) output).

The computing device 1800 may include another output device 1818 (or corresponding interface circuitry, as discussed above). Examples of the other output device 1818 may include an audio codec, a video codec, a printer, a wired or wireless transmitter for providing information to other devices, or an additional storage device.

The computing device 1800 may include another input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 1800 may include a global positioning system (GPS) device 1822 (or corresponding interface circuitry, as discussed above). The GPS device 1822 may be in communication with a satellite-based system and may receive a location of the computing device 1800, as known in the art.

The computing device 1800 may include a security interface device 1824. The security interface device 1824 may include any device that provides security features for the computing device 1800 or for any individual components therein (e.g., for the processing device 1802 or for the memory 1804). Examples of security features may include authorization, access to digital certificates, access to items in keychains, etc. Examples of the security interface device 1824 may include a software firewall, a hardware firewall, an antivirus, a content filtering device, or an intrusion detection device.

In some embodiments, the computing device 1800 may include a temperature detection device 1826 and a temperature regulation device 1828.

The temperature detection device 1826 may include any device capable of determining temperatures of the computing device 1800 or of any individual components therein (e.g., temperatures of the processing device 1802 or of the memory 1804). In various embodiments, the temperature detection device 1826 may be configured to determine temperatures of an object (e.g., the computing device 1800, components of the computing device 1800, devices coupled to the computing device, etc.), temperatures of an environment (e.g., a data center that includes, is controlled by, or otherwise associated with the computing device 1800), and so on. The temperature detection device 1826 may include one or more temperature sensors. Different temperature sensors of the temperature detection device 1826 may have different locations within and around the computing device 1800. A temperature sensor may generate data (e.g., digital data) representing detected temperatures and provide the data to another device, e.g., to the temperature regulation device 1828, the processing device 1802, the memory 1804, etc. In some embodiments, a temperature sensor of the temperature detection device 1826 may be turned on or off, e.g., by the processing device 1802 or an external system. The temperature sensor detects temperatures when it is on and does not detect temperatures when it is off. In other embodiments, a temperature sensor of the temperature detection device 1826 may detect temperatures continuously and automatically or detect temperatures at predefined times or at times triggered by an event associated with the computing device 1800 or any components therein.

The temperature regulation device 1828 may include any device configured to change (e.g., decrease) temperatures, e.g., based on one or more target temperatures and/or based on temperature measurements performed by the temperature detection device 1826. A target temperature may be a preferred temperature. A target temperature may depend on a setting in which the computing device 1800 operates. In some embodiments, the target temperature may be 200 Kelvin degrees or lower. In some embodiments, the target temperature may be 20 Kelvin degrees or lower, or 5 Kelvin degrees or lower. Target temperatures for different objects and different environments of, or associated with, the computing device 1800 can be different. In some embodiments, cooling provided by the temperature regulation device 1828 may be a multi-stage process with temperatures ranging from room temperature to 4K or lower.

In some embodiments, the temperature regulation device 1828 may include one or more cooling devices. Different cooling devices may have different locations within and around the computing device 1800. A cooling device of the temperature regulation device 1828 may be associated with one or more temperature sensors of the temperature detection device 1826 and may be configured to operate based on temperatures detected by the temperature sensors. For instance, a cooling device may be configured to determine whether a detected ambient temperature is above the target temperature or whether the detected ambient temperature is higher than the target temperature by a predetermined value or determine whether any other temperature-related condition associated with the temperature of the computing device 1800 is satisfied. In response to determining that one or more temperature-related condition associated with the temperature of the computing device 1800 are satisfied (e.g., in response to determining that the detected ambient temperature is above the target temperature), a cooling device may trigger its cooling mechanism and start to decrease the ambient temperature. Otherwise, the cooling device does not trigger any cooling. A cooling device of the temperature regulation device 1828 may operate with various cooling mechanisms, such as evaporation cooling, radiation cooling, conduction cooling, convection cooling, other cooling mechanisms, or any combination thereof. A cooling device of the temperature regulation device 1828 may include a cooling agent, such as water, oil, liquid nitrogen, liquid helium, etc. In some embodiments, the temperature regulation device 1828 may be, for example, a dilution refrigerator, a helium-3 refrigerator, or a liquid helium refrigerator. In some embodiments, the temperature regulation device 1828 or any portions thereof (e.g., one or more of the individual cooling devices) may be connected to the computing device 1800 in close proximity (e.g., less than about 1 meter) or may be provided in a separate enclosure where a dedicated heat exchanger (e.g., a compressor, a heating, ventilation, and air conditioning (HVAC) system, liquid helium, liquid nitrogen, etc.) may reside.

By maintaining the target temperatures, the energy consumption of the computing device 1800 (or components thereof) can be reduced, while the computing efficiency may be improved. For example, when the computing device 1800 (or components thereof) operates at lower temperatures, energy dissipation (e.g., heat dissipation) may be reduced. Further, energy consumed by semiconductor components (e.g., energy needed for switching transistors of any of the components of the computing device 1800) can also be reduced. Various semiconductor materials may have lower resistivity and/or higher mobility at lower temperatures. That way, the electrical current per unit supply voltage may be increased by lowering temperatures. Conversely, for the same current that would be needed, the supply voltage may be lowered by lowering temperatures. As energy corelates to the supply voltage, the energy consumption of the semiconductor components may lower too. In some implementations, the energy savings due to reducing heat dissipation and reducing energy consumed by semiconductor components of the computing device or components thereof may outweigh (sometimes significantly outweigh) the costs associated with energy needed for cooling.

The computing device 1800 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 1800 may be any other electronic device that processes data.

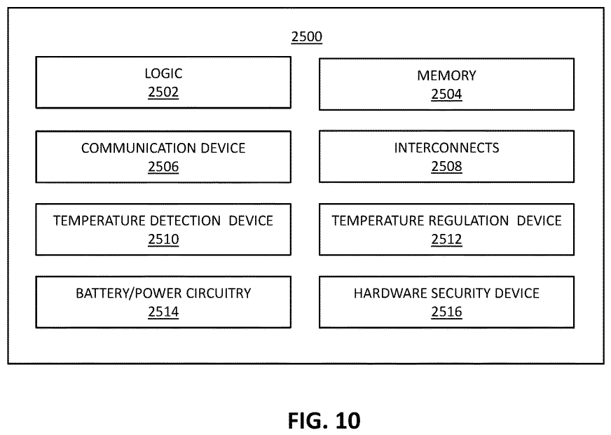

FIG. 10 is a block diagram of an example processing device 2500 that may include one or more IC devices with one or more metal layers with at least one diode in accordance with any of the embodiments disclosed herein. For example, any suitable ones of the components of the processing device 2500 may include a die (e.g., the die 1502 of FIG. 8) having one or more metal layers with at least one diode as described herein. Any one or more of the components of the processing device 2500 may include, or be included in, an IC device 1600 of FIG. 9 or an IC device assembly 1700 of FIG. 10. Any one or more of the components of the processing device 2500 may include, or be included in, a computing device 1800 of FIG. 9; for example, the processing device 2500 may be the processing device 1802 of the computing device 1800.

A number of components are illustrated in FIG. 10 as included in the processing device 2500, but any one or more of these components may be omitted or duplicated, as suitable for the application. In some embodiments, some or all of the components included in the processing device 2500 may be attached to one or more motherboards. In some embodiments, some or all of these components are fabricated on a single SoC die or coupled to a single support structure, e.g., to a single carrier substrate.

Additionally, in various embodiments, the processing device 2500 may not include one or more of the components illustrated in FIG. 10, but the processing device 2500 may include interface circuitry for coupling to the one or more components. For example, the processing device 2500 may not include a memory 2504, but may include display device interface circuitry (e.g., a connector and driver circuitry) to which a memory 2504 may be coupled.

The processing device 2500 may include logic circuitry 2502 (e.g., one or more circuits configured to implement logic/compute functionality). Examples of such circuits include ICs implementing one or more of input/output (I/O) functions, arithmetic operations, pipelining of data, etc.

In some embodiments, the logic circuitry 2502 may include one or more circuits responsible for read/write operations with respect to the data stored in the memory 2504. To that end, the logic circuitry 2502 may include one or more I/O ICs configured to control access to data stored in the memory 2504.

In some embodiments, the logic circuitry 2502 may include one or more high-performance compute dies, configured to perform various operations with respect to data stored in the memory 2504 (e.g., arithmetic and logic operations, pipelining of data from one or more memory dies of the memory 2504, and possibly also data from external devices/chips). In some embodiments, the logic circuitry 2502 may be configured to only control I/O access to data but not perform any operations on the data. In some embodiments, the logic circuitry 2502 may implement ICs configured to implement I/O control of data stored in the memory 2504, assemble data from the memory 2504 for transport (e.g., transport over a central bus) to devices/chips that are either internal or external to the processing device 2500, etc. In some embodiments, the logic circuitry 2502 may not be configured to perform any operations on the data besides I/O and assembling for transport to the memory 2504.

The processing device 2500 may include a memory 2504, which may include one or more ICs configure to implement memory circuitry (e.g., ICs implementing one or more of memory devices, memory arrays, control logic configured to control the memory devices and arrays, etc.). In some embodiments, the memory 2504 may be implemented substantially as described above with reference to the memory 1804 (FIG. 9). In some embodiments, the memory 2504 may be a designated device configured to provide storage functionality for the components of the processing device 2500 (i.e., local), while the memory 1804 may be configured to provide system-level storage functionality for the entire computing device 1800 (i.e., global). In some embodiments, the memory 2504 may include memory that shares a die with the logic circuitry 2502.

In some embodiments, the memory 2504 may include a flat memory (also sometimes referred to as a “flat hierarchy memory” or a “linear memory”) and, therefore, may also be referred to as a “basin memory.” As known in the art, a flat memory or a linear memory refers to a memory addressing paradigm in which memory may appear to the program as a single contiguous address space, where a processor can directly and linearly address all of the available memory locations without having to resort to memory segmentation or paging schemes. Thus, the memory implemented in the memory 2504 may be a memory that is not divided into hierarchical layer or levels in terms of access of its data.

In some embodiments, the memory 2504 may include a hierarchical memory. In this context, hierarchical memory refers to the concept of computer architecture where computer storage is separated into a hierarchy based on features of memory such as response time, complexity, capacity, performance, and controlling technology. Designing for high performance may require considering the restrictions of the memory hierarchy, i.e., the size and capabilities of each component. With hierarchical memory, each of the various memory components can be viewed as part of a hierarchy of memories (m₁, m₂, . . . , mₙ) in which each member m; is typically smaller and faster than the next highest member mᵢ₊₁ of the hierarchy. To limit waiting by higher levels, a lower level of a hierarchical memory structure may respond by filling a buffer and then signaling for activating the transfer. For example, in some embodiments, the hierarchical memory implemented in the memory 2504 may be separated into four major storage levels: 1) internal storage (e.g., processor registers and cache), 2) main memory (e.g., the system RAM and controller cards), and 3) on-line mass storage (e.g., secondary storage), and 4) off-line bulk storage (e.g., tertiary, and off-line storage). However, as the number of levels in the memory hierarchy and the performance at each level has increased over time and is likely to continue to increase in the future, this example hierarchical division provides only one non-limiting example of how the memory 2504 may be arranged.

The processing device 2500 may include a communication device 2506, which may be implemented substantially as described above with reference to the communication chip 1806 (FIG. 9). In some embodiments, the communication device 2506 may be a designated device configured to provide communication functionality for the components of the processing device 2500 (i.e., local), while the communication chip 1806 may be configured to provide system-level communication functionality for the entire computing device 1800 (i.e., global).

The processing device 2500 may include interconnects 2508, which may include any element or device that includes an electrically conductive material for providing electrical connectivity to one or more components of, or associated with, a processing device 2500 or/and between various such components. Examples of the interconnects 2508 include conductive lines/wires (also sometimes referred to as “lines” or “metal lines” or “trenches”) and conductive vias (also sometimes referred to as “vias” or “metal vias”), metallization stacks, redistribution layers, metal-insulator-metal (MIM) structures, etc.

The processing device 2500 may include a temperature detection device 2510 which may be implemented substantially as described above with reference to the temperature detection device 1826 of FIG. 10 but configured to determine temperatures on a more local scale, i.e., of the processing device 2500 of components thereof. In some embodiments, the temperature detection device 2510 may be a designated device configured to provide temperature detection functionality for the components of the processing device 2500 (i.e., local), while the temperature detection device 1826 may be configured to provide system-level temperature detection functionality for the entire computing device 1800 (i.e., global).

The processing device 2500 may include a temperature regulation device 2512 which may be implemented substantially as described above with reference to the temperature regulation device 1828 of FIG. 9 but configured to regulate temperatures on a more local scale, i.e., of the processing device 2500 of components thereof. In some embodiments, the temperature regulation device 2512 may be a designated device configured to provide temperature regulation functionality for the components of the processing device 2500 (i.e., local), while the temperature regulation device 1828 may be configured to provide system-level temperature regulation functionality for the entire computing device 1800 (i.e., global).

The processing device 2500 may include a battery/power circuitry 2514 which may be implemented substantially as described above with reference to the battery/power circuitry 1810 of FIG. 9. In some embodiments, the battery/power circuitry 2514 may be a designated device configured to provide battery/power functionality for the components of the processing device 2500 (i.e., local), while the battery/power circuitry 1810 may be configured to provide system-level battery/power functionality for the entire computing device 1800 (i.e., global).

The processing device 2500 may include a hardware security device 2516 which may be implemented substantially as described above with reference to the security interface device 1824 of FIG. 10. In some embodiments, the hardware security device 2516 may be a physical computing device configured to safeguard and manage digital keys, perform encryption and decryption functions for digital signatures, authentication, and other cryptographic functions. In some embodiments, the hardware security device 2516 may include one or more secure cryptoprocessors chips.

### SELECT EXAMPLES

The following paragraphs provide various examples of the embodiments disclosed herein.

Example 1 provides a device including a layer of a dielectric material; a first via and a second via extending at least partially through the layer; and a stack within the layer, the stack including a first metal plate coupled to the first via; a second metal plate at least partially over the first metal plate, the second metal plate coupled to the second via; and an insulator between the first metal plate and the second metal plate.

Example 2 provides the device of example 1, where the insulator has a thickness measured between the first metal plate and the second metal plate of less than 10 nanometers.

Example 3 provides the device of example 1 or 2, where the insulator includes oxygen.

Example 4 provides the device of example 3, where the insulator further includes at least one of hafnium, titanium, tantalum, and nickel.

Example 5 provides the device of example 1 or 2, where the insulator includes nitrogen.

Example 6 provides the device of any preceding example, where the insulator is a first insulator, the stack including a second insulator between the first insulator and the second metal plate.

Example 7 provides the device of any preceding example, where the layer of dielectric material is over a device layer including a plurality of transistors, and the first via is electrically coupled to at least one transistor in the device layer.

Example 8 provides the device of example 7, where the second via is coupled to an electrical ground.

Example 9 provides a device, such as IC device, including a first via and a second via in a metallization stack of the IC device; and a diode including a first metal plate coupled to the first via; a second metal plate at least partially over the first metal plate, the second metal plate coupled to the second via; and a semiconductor region between the first metal plate and the second metal plate.

Example 10 provides the IC device of example 9, where the semiconductor region includes a first layer of a first semiconductor and a second layer of a second semiconductor.

Example 11 provides the IC device of example 10, where the first semiconductor is an n-type semiconductor, and the second semiconductor is a p-type semiconductor.

Example 12 provides the IC device of any of examples 9-11, where the diode further includes an insulator region between the first metal plate and the semiconductor region.

Example 13 provides the IC device of any of examples 9-12, where the metallization stack is over a device layer including a plurality of transistors, and the first via is electrically coupled to at least one transistor in the device layer.

Example 14 provides the IC device of example 13, where the second via is coupled to an electrical ground.

Example 15 provides the IC device of any of examples 9-14, where the first metal plate has a longest dimension extending in a first direction, and the second metal plate also has a longest dimension extending in the first direction.

Example 16 provides the IC device of any of examples 9-14, where the first metal plate has a longest dimension extending in a first direction, and the second metal plate has a longest dimension extending in a second direction, the second direction perpendicular to the first direction.

Example 17 provides an IC device including a device layer including a plurality of transistors; and a metallization layer over the device layer, the metallization layer including a first via and a second via extending at least partially through the metallization layer; and a diode coupled to the first via and the second via, the diode including a metal and at least one of an insulator and a semiconductor.

Example 18 provides the IC device of example 17, the metallization layer further including a second diode.

Example 19 provides the IC device of example 18, where the second diode is coupled to the second via and a third via.

Example 20 provides the IC device of any of examples 17-19, where the metallization layer further includes a dielectric material and at least one metal line, and the diode is over the metal line and separated from the metal line by the dielectric material.

Example 21 provides an IC package that includes an IC die, including one or more of the IC devices according to any one of the preceding examples. The IC package may also include a further component, coupled to the IC die.

Example 22 provides the IC package according to example 21, where the further component is one of a package substrate, a flexible substrate, or an interposer.

Example 23 provides the IC package according to examples 21 or 22, where the further component is coupled to the IC die via one or more first level interconnects.

Example 24 provides the IC package according to example 23, where the one or more first level interconnects include one or more solder bumps, solder posts, or bond wires.

Example 25 provides a computing device that includes a circuit board; and an IC die coupled to the circuit board, where the IC die includes one or more of the transistor/IC devices according to any one of the preceding examples (e.g., transistor/IC devices according to any one of examples 1-20), and/or the IC die is included in the IC package according to any one of the preceding examples (e.g., the IC package according to any one of examples 21-24).

Example 26 provides the computing device according to example 25, where the computing device is a wearable computing device (e.g., a smart watch) or hand-held computing device (e.g., a mobile phone).

Example 27 provides the computing device according to examples 25 or 26, where the computing device is a server processor.

Example 28 provides the computing device according to examples 25 or 26, where the computing device is a motherboard.

Example 29 provides the computing device according to any one of examples 25-28, where the computing device further includes one or more communication chips and an antenna.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

What is claimed is:

1. A device comprising:
a layer of a dielectric material;
a first via and a second via extending at least partially through the layer; and
a stack within the layer, the stack comprising:
a first metal plate coupled to the first via;
a second metal plate at least partially over the first metal plate, the second metal plate coupled to the second via; and
an insulator between the first metal plate and the second metal plate.

2. The device of claim 1, wherein the insulator has a thickness measured between the first metal plate and the second metal plate of less than 10 nanometers.

3. The device of claim 1, wherein the insulator comprises oxygen.

4. The device of claim 3, wherein the insulator further comprises at least one of hafnium, titanium, tantalum, and nickel.

5. The device of claim 1, wherein the insulator comprises nitrogen.

6. The device of claim 1, wherein the insulator is a first insulator, the stack comprising a second insulator between the first insulator and the second metal plate.

7. The device of claim 1, wherein the layer of dielectric material is over a device layer comprising a plurality of transistors, and the first via is electrically coupled to at least one transistor in the device layer.

8. The device of claim 7, wherein the second via is coupled to an electrical ground.

9. A device comprising:
a first via and a second via in a metallization stack of the device; and
a diode comprising:
a first metal plate coupled to the first via;
a second metal plate at least partially over the first metal plate, the second metal plate coupled to the second via; and
a semiconductor region between the first metal plate and the second metal plate.

10. The device of claim 9, wherein the semiconductor region comprises a first layer of a first semiconductor and a second layer of a second semiconductor.

11. The device of claim 10, wherein the first semiconductor is an n-type semiconductor, and the second semiconductor is a p-type semiconductor.

12. The device of claim 9, wherein the diode further comprises an insulator region between the first metal plate and the semiconductor region.

13. The device of claim 9, wherein the metallization stack is over a device layer comprising a plurality of transistors, and the first via is electrically coupled to at least one transistor in the device layer.

14. The device of claim 13, wherein the second via is coupled to an electrical ground.

15. The device of claim 9, wherein the first metal plate has a longest dimension extending in a first direction, and the second metal plate also has a longest dimension extending in the first direction.

16. The device of claim 9, wherein the first metal plate has a longest dimension extending in a first direction, and the second metal plate has a longest dimension extending in a second direction, the second direction perpendicular to the first direction.

17. An integrated circuit (IC) device comprising:
a device layer comprising a plurality of transistors; and
a metallization layer over the device layer, the metallization layer comprising:
a first via and a second via extending at least partially through the metallization layer; and
a diode coupled to the first via and the second via, the diode comprising a metal and at least one of an insulator and a semiconductor.

18. The IC device of claim 17, the metallization layer further comprising a second diode.

19. The IC device of claim 18, wherein the second diode is coupled to the second via and a third via.

20. The IC device of claim 17, wherein the metallization layer further comprises a dielectric material and at least one metal line, and the diode is over the metal line and separated from the metal line by the dielectric material.
